(19) United States
(12) Patent Application Publication
(10) Pub. No.: US 2013/0053250 A1
(43) Pub. Date: Feb. 28, 2013

(54) Nb3Sn SUPERCONDUCTOR WIRE AND METHOD FOR MANUFACTURING Nb3Sn SUPERCONDUCTOR WIRE

(71) Applicants: Katsumi OHATA, Tsuchiura (JP); Yoshihide WADAYAMA, Hitachiota (JP); Kazuhiko NAKAGAWA, Tsuchiura (JP); Morio KIMURA, Kasumigaura (JP)

(72) Inventors: Katsumi OHATA, Tsuchiura (JP); Yoshihide WADAYAMA, Hitachiota (JP); Kazuhiko NAKAGAWA, Tsuchiura (JP); Morio KIMURA, Kasumigaura (JP)

(73) Assignee: HITACHI CABLE, LTD., TOKYO (JP)

(21) Appl. No.: 13/593,020

(22) Filed: Aug. 23, 2012

(30) Foreign Application Priority Data
Aug. 25, 2011 (JP) 2011-184097
Aug. 20, 2012 (JP) 2012-181532

(51) Int. Cl. H01B 12/10; H01L 39/24

(52) U.S. Cl. 505/231; 505/433; 29/599; 174/125.1

(57) ABSTRACT

An Nb₃Sn superconductor wire is manufactured by heating a precursor for an Nb₃Sn superconductor wire. The precursor includes a Cu tube made of Cu or Cu-alloy, assemblies, each of which includes Nb filaments disposed in the Cu tube, and each of the Nb filaments includes an Nb core made of Nb or Nb-alloy. Each of the assemblies also includes Sn filaments disposed in the Cu tube, and each of the Sn filaments includes a Sn core made of Sn or Sn-alloy. The precursor also includes reinforcing filaments disposed in the Cu tube for dividing the assemblies such that the assemblies are not adjacent to each other. By heating the precursor, Sn in the Sn core is diffused into the Nb core to produce Nb₃Sn.

The present application is based on Japanese Patent Application No. 2011-184097 filed on Aug. 25, 2011 and Japanese Patent Application No. 2012-181532 filed on Aug. 20, 2012, the entire contents of which are incorporated herein by reference.

### BACKGROUND OF THE INVENTION

1. Field of the Invention

The present invention relates to an Nb₃Sn superconductor wire having high critical current density (Jc) characteristic and high strength to be applicable for a high-field magnet, and a method for manufacturing an Nb₃Sn superconductor wire.

2. Related Art

As a method for manufacturing an Nb₃Sn superconductor wire, the bronze method has been used widely. The bronze method is a method including steps of forming a wire with a configuration in which a lot of Nb filaments are disposed within Cu—Sn based alloy matrix, i.e. so-called bronze matrix, diffusing Sn of the Cu—Sn based alloy into the Nb filaments by heat treatment to produce Nb₃Sn in some portions of the Nb filaments, thereby providing a superconductor wire. For example, Japanese Patent Application Laid-Open No. 2010-129453 (JP-A 2010-129453) discloses the bronze method.

However, since an upper limit of solubility limit of Sn in the Cu—Sn based alloy is about 16% by weight, it is not possible to produce Nb₃Sn to be greater than 16% by weight, so that there is a limit in critical current value (Ic).

Therefore, the internal Sn diffusion methods for providing more Sn by using a source of Sn other than Cu—Sn based alloy have been developed. One representative example of the internal Sn diffusion methods will be explained as follows. Sn or Sn-alloy is disposed as Sn source at a center portion of the Cu matrix, a plurality of Nb filaments are provided around the Cu matrix, and a Ta or Nb barrier layer is provided around a periphery of the plurality of the Nb filaments, to provide a sub element billet. Sub element billets are bundled to provide a multicore wire. Thereafter, the multicore wire is heat-treated, so that Sn is diffused from the Sn layer via the Cu matrix into the Nb filaments. As a result, Nb₃Sn is produced in the portion of the Nb filaments.

According to the internal Sn diffusion method, it is possible to increase a proportion of Sn composite material compared to the bronze method, so that a high characteristic e.g. non-Cu Jc (the critical current density in the non-copper part area)=2900 A/mm² in 12 T (tesla) as the critical current density (Jc) of the wire rod is obtained. For example, such a method is disclosed by J. A. Parrell et al., “Highfield Nb₃Sn conductor development at Oxford Superconducting Technology” IEEE Trans. Appl. Supercond., 2003, vol. 13, No. 2, pp. 3470-3473.

In the internal Sn diffusion method, after a sub element billet is formed, it is necessary to carry out a drawing process on the sub element billet to reduce a diameter thereof until a size suitable for incorporation into the multicore wire. In the internal Sn diffusion method as described above, however, the sub element includes Sn having an extremely small mechanical strength, and the sub element also includes Nb (or Ta) having a high hardness compared with Sn. Therefore, when Sn and Nb (or Ta) are processed simultaneously, Sn may greatly deform so that non-uniform cross-section may be provided.

Accordingly, as another method for manufacturing a wire rod according to the internal Sn diffusion method, a following method is proposed by e.g. Japanese Patent Application Laid-Open No. 2006-4684 (JP-A 2006-4684). In such a method, a multicore Nb filament including multiple Nb cores provided in a Cu matrix and a single core Sn filament including Sn and Cu provided at an outer periphery of Sn are prepared separately, and a plurality of multicore Nb filaments and single core Sn filaments are combined to be a composite multicore wire.

In the case of manufacturing a superconductor magnet by using a superconductor wire, an electromagnetic stress σ (electromagnetic force per unit cross-section of a wire) (MPa) is generated in a winding wire (magnet wire) in the superconductor magnet along a direction for wire drawing.

The electromagnetic stress σ is expressed by σ=B×J×R, wherein a flowing current per unit cross-section of the superconductor wire is J (A/mm²), a magnitude of a magnetic field (magnetic flux density) in the winding wire is B (T), and a radius of the winding wire in the superconductor magnet is R (mm).

The superconductor wire manufactured by the internal Sn diffusion method (hereinafter, referred to as “internal diffusion wire”) is characterized by a high critical current density (Jc) of the wire. The magnetic field generated by the magnet using the internal diffusion wire can be advantageously increased, while the electromagnetic force to be applied to the superconductor wire is also increased as expressed by the above formula.

In general, it has been known that the critical current density (Jc) characteristic of the Nb₃Sn filament is sensitive to distortion, and that the critical current density (Jc) falls when a distortion (strain) of about 1% is applied to the Nb₃Sn filament. Therefore, in the case of manufacturing a high magnetic field magnet, a composite wire including reinforcing members that are incorporated within a superconductor wire. As to a disposition of the reinforcing members in the cross-section of the superconductor wire, the conventional superconductor wire manufactured by the bronze method (hereinafter, referred to as “bronze method wire”) or the conventional internal diffusion wire has been configured such that superconducting filaments in vicinity of a center part of the multicore wire are replaced with the reinforcing members such as Ta for the number as required.

Further, in general, the superconductor wire has been configured as a multicore structure in order to reduce the AC loss. Since a magnetic susceptibility causing the AC loss is proportional to a diameter of the superconducting filament, a lot of fine superconducting filaments are composed together to provide a composite superconductor wire. Further, when respective superconducting filaments are provided too closely, the respective superconducting filaments will be coupled with each other as a superconductor, so that the AC loss cannot be reduced. Therefore, the respective superconducting filaments are separated from each other by providing a space (distance) therebetween such that the respective superconducting filaments would not be provided too closely.

In the internal diffusion wire composed of a multicore wire including a plurality of sub elements each of which includes a plurality of Nb filaments and Sn filaments, since the Nb filaments in the sub element are coupled with each other, the sub elements are electromagnetically separated (isolated) from each other by spatially separating the sub elements from each other by appropriately setting a clearance (interval) therebetween. In the Nb₃Sn superconductor wire formed of the internal diffusion wire comprising a multicore wire including sub elements each of which includes a single Sn filament and sub elements each of which includes a plurality of Nb filaments (as disclosed by Parrell et al.) or sub elements each of which includes a single Nb filament, adjacent Nb sub elements are disposed with a spacing such that the adjacent Nb sub elements would not be tightly close to each other.

### SUMMARY OF THE INVENTION

In the bronze method, the Cu—Sn based alloy is used as a source of Sn for supplying Sn into Nb, thereby generating Nb₃Sn. Since the Cu—Sn based alloy has a high hardness, there is not a large hardness difference between the Cu—Sn based alloy and the Nb filament or the reinforcing members such as Ta, so that a hardness distribution at the cross-section of the wire is not large. Therefore, the wire can be processed uniformly during the wire drawing.

On the other hand, an extremely soft Sn material is incorporated alone in the internal diffusion wire. If the reinforcing members made of Ta are disposed at the center part of the multicore wire and Sn is provided at the outer periphery of the multicore wire as in the conventional device, the hardness distribution at the cross-section of the multicore wire will be large, so that a non-uniform deformation of the cross-section of the wire, breakage of the wire, and the like may be caused during the wire drawing.

Further, in the method of replacing the center filaments of the multicore wire with the reinforcing members, the strength of the entire wire can be improved by the incorporation of the reinforcing members, however, the distortion may be caused due to the absence of the reinforcing member in each Nb₃Sn filament. Namely, in the situation that a tensile strain is applied to the wire in a longitudinal direction, the strength will be enhanced in proportion with a composite ratio of the reinforcing members regardless of the position of the reinforcing members in the wire. However, the distortion actually applied to the wire is not only the tensile strain in the longitudinal direction of the wire. For example, in the case of stranding a plurality of wires thereby providing a superconductor, the respective wires in the stranded superconductor wire are intersected with each other, so that a local bending distortion or a compressive distortion in a lateral direction will occur. In such a case, even though the reinforcing member is disposed at the center part of the multicore wire, the distortion will be applied to the respective filaments, so that the degradation in wire characteristics will be caused.

The Nb₃Sn superconductor wire manufactured by the internal diffusion method has an advantage in that the high critical current characteristic can be provided because of much Sn content at the cross-section. On the other hand, it is necessary to provide a composite Nb with a quantity corresponding to the quantity of the increased Sn for producing Nb₃Sn with a quantity corresponding to the quantity of the increased Sn. When the number of the Nb filaments is increased, the distance between the respective Nb filaments tends to be closer to each other, and the Nb₃Sn filaments that are finally produced by the heat-treatment tend to be easily coupled with each other superconductively. On the contrary, since the spacing between the filaments is limited to prevent the filaments from the mutual coupling, the quantity of the composite Nb filaments was limited and the critical current characteristic was also limited.

Accordingly, an object of the present invention is to provide an Nb₃Sn superconductor wire having high critical current density (Jc) characteristic, in which the degradation in superconducting characteristics with respect to the compression (degradation rate of the critical current density) can be suppressed, and a method for manufacturing an Nb₃Sn superconductor wire.

According to a feature of the invention, an Nb₃Sn superconductor wire manufactured by heating a precursor for an Nb₃Sn superconductor wire, the precursor comprises:

a Cu tube comprising Cu or Cu-alloy;

assemblies, each of which comprises Nb filaments disposed in the Cu tube, each of the Nb filaments comprising an Nb core comprising Nb or Nb-alloy, and Sn filaments disposed in the Cu tube, each of the Sn filaments comprising a Sn core comprising Sn or Sn-alloy; and

reinforcing filaments disposed in the Cu tube for dividing the assemblies such that the assemblies are not adjacent to each other,

in which Sn in the Sn core is diffused into the Nb core by the heating to produce Nb₃Sn.

The number of the assemblies divided by the reinforcing filaments may be 6n+1 (n is an integer).

A part of the reinforcing filaments may comprise a core and a coating layer for coating the core, and the core may comprise at least one metal selected from a group consisting of Ta, Ta-alloy, W, W-alloy, Nb, Nb-alloy, Ti, Ti-alloy, Mo, Mo-alloy, V, V-alloy, Zr, Zr-alloy, Hf and Hf-alloy.

A part of the reinforcing filaments may be replaced with Cu filaments comprising Cu or Cu-alloy.

The reinforcing filaments may be disposed to surround 70% or more and 90% or less of a periphery of the assemblies after being divided.

According to another feature of the invention, a method for manufacturing an Nb₃Sn superconductor wire comprises:

conducting area reduction on a Cu pipe to which an Nb core comprising Nb or Nb-alloy is inserted, thereby providing Nb filaments;

conducting area reduction on a Sn core comprising Sn or Sn-alloy, or on a Cu pipe to which the Sn core is inserted, thereby providing Sn filaments;

conducting area reduction on a reinforcing core, or on a Cu pipe to which the reinforcing core is inserted, thereby providing reinforcing filaments;

forming a barrier layer comprising a metal selected from the group consisting of Ta, Ta-alloy, Nb and Nb-alloy at an inner surface of a Cu tube;

disposing assemblies comprising the Nb filaments and the Sn filaments inside the barrier layer with dividing the assemblies by the reinforcing filaments, such that the assemblies are not adjacent to each other;

conducting area reduction on the Cu tube, thereby providing a precursor for the Nb₃Sn superconductor wire;

heating the precursor for the Nb₃Sn superconductor wire to diffuse Sn in the Sn core into the Nb core, thereby producing Nb₃Sn.

### EFFECTS OF THE INVENTION

According to the present invention, it is possible to provide an Nb₃Sn superconductor wire having high critical current density (Jc) characteristic, in which the degradation in superconducting characteristics with respect to the compression (degradation rate of the critical current density) can be suppressed, and a method for manufacturing an Nb₃Sn superconductor wire.

### BRIEF DESCRIPTION OF THE DRAWINGS

Next, a precursor for an Nb₃Sn superconductor wire and a method for manufacturing an Nb₃Sn superconductor wire in an embodiment according to the invention will be explained in conjunction with appended drawings, wherein:

FIG. 1 is a lateral cross-sectional view showing a cross-sectional structure of a precursor for an Nb₃Sn superconductor wire in the embodiment according to the present invention and Example 1;

FIG. 2A is a lateral cross-sectional view showing a cross-sectional structure of a precursor for an Nb₃Sn superconductor wire in Examples 2, 4 and 5;

FIG. 2B is a lateral cross-sectional view showing a cross-sectional structure of a precursor for an Nb₃Sn superconductor wire in Example 6;

FIG. 3 is a lateral cross-sectional view showing a cross-sectional structure of a precursor for an Nb₃Sn superconductor wire in Example 3;

FIG. 4 is a lateral cross-sectional view showing a cross-sectional structure of a precursor for an Nb₃Sn superconductor wire in Example 7;

FIG. 5 is a lateral cross-sectional view showing a cross-sectional structure of a precursor for an Nb₃Sn superconductor wire in Example 8;

FIG. 6 is a lateral cross-sectional view showing a cross-sectional structure of a precursor for an Nb₃Sn superconductor wire manufactured by the conventional internal Sn diffusion method in comparative examples 1 and 2;

FIG. 7 is a lateral cross-sectional view showing a cross-sectional structure of a precursor for Nb₃Sn superconductor wire manufactured by the conventional internal Sn diffusion method in comparative example 3;

FIG. 8 is an explanatory diagram for showing a process of a lateral compression test;

FIG. 9 is a graph showing an example of a measured data of a magnetic sensitivity; and

FIG. 10 is graphs showing each current-voltage characteristic obtained by measuring a critical current value Ic in Examples 4 to 8.

### DETAILED DESCRIPTION OF THE EMBODIMENT

Next, the embodiment according to the present invention, examples and comparative examples will be described in more detail in conjunction with appended drawings. In the respective drawings, the same reference numeral is assigned to the elements having the substantially same function, and a redundant description thereof will be omitted.

### Summary of the Embodiment

The embodiment of the present invention is summarized as an Nb₃Sn superconductor wire manufactured by heating a precursor for an Nb₃Sn superconductor wire, the precursor comprising a Cu tube comprising Cu or Cu-alloy, assemblies, each of which comprises Nb filaments disposed in the Cu tube, each of the Nb filaments comprising an Nb core comprising Nb or Nb-alloy, and Sn filaments disposed in the Cu tube, each of the Sn filaments comprising a Sn core comprising Sn or Sn-alloy, and reinforcing filaments disposed in the Cu tube for dividing the assemblies such that the assemblies are not adjacent to each other, and Sn in the Sn core is diffused into the Nb core by the heating to produce Nb₃Sn.

Herein, the limitation “such that the assemblies are not adjacent with each other” means that the reinforcing filaments exist between the assemblies. According to this structure, since the Nb filaments constituting the assembly can be disposed to be closer to each other, the number of the Nb filaments can be increased, so that a total cross-sectional area of the Nb core with respect to a lateral cross-sectional area of the precursor for an Nb₃Sn superconductor wire can be increased. Further, the compressive strain can be suppressed by the reinforcing filaments.

### The Embodiment

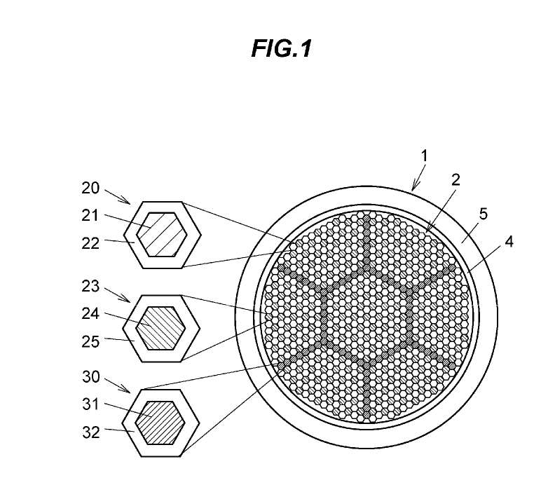

FIG. 1 is a lateral cross-sectional view showing a cross-sectional structure of a precursor for Nb₃Sn superconductor wire in the embodiment according to the present invention.

Referring to FIG. 1, a precursor 1 for an Nb₃Sn superconductor wire includes a Cu tube 5 comprising Cu or a Cu-alloy, a Ta barrier layer 4 provided inside the Cu tube 5, a plurality (seven in this embodiment) of assemblies of Nb filaments (filament assemblies) 2 provided inside the Ta barrier layer 4, and a plurality of Ta filaments 30 provided inside the Ta barrier layer 4 for dividing the filament assemblies 2 such that the filament assemblies 2 are not adjacent to each other, namely, do not come into contact with each other. The precursor 1 for an Nb₃Sn superconductor wire is heat-treated, and then Nb₃Sn is produced by Sn diffused into the Nb filaments, to provide an Nb₃Sn superconductor wire. The method for manufacturing the Nb₃Sn superconductor wire will be explained later.

Herein, the “filament” means each core in a superconductor precursor. The “filament” also means a core material itself before it is incorporated into the superconductor precursor. The “Cu matrix” means a copper part (namely, copper coating and copper filaments to be described below) of the superconductor precursor. The “filament assembly” means an assembly of filaments with focusing on the Nb or Sn cores (the portion other than Cu matrix).

Ta barrier layer 4 is provided for suppressing the inter-diffusion of Cu and Sn between the filament assemblies 2 and the Cu tube 2. The material of the Ta barrier layer 4 is not limited to Ta, and Ta-alloy, Nb or Nb-alloy may be used.

The filament assembly 2 is composed of plurality of Nb filaments 20 and Sn filaments 23. In addition, it is preferable that the filament assemblies 2 are disposed in the Cu tube 5 such that the Sn filaments 23 are not adjacent to each other.

The Nb filament 20 comprises an Nb core (Nb filament) 21 composed of Nb or Nb-alloy with a hexagonal cross-section and a Cu coating layer 22 composed of Cu or Cu-alloy which coats a surface of the Nb core 21. The Nb filament 20 has a hexagonal cross-section in an entire shape.

The Sn filament 23 comprises a Sn core (Sn filament) 24 composed of Sn or Sn-alloy with a hexagonal cross-section and a Cu coating layer 25 composed of Cu or Cu-alloy which coats a surface of the Sn core 24. The Sn filament 23 has a hexagonal cross-section in an entire shape.

The Ta filament 30 comprises a Ta core 31 composed of Ta or Ta-alloy with a hexagonal cross-section and a Cu coating layer 32 composed of Cu or Cu-alloy which coats a surface of the Ta core 31. The Ta filament 30 has a hexagonal cross-section in an entire shape. Herein, the Ta filament 30 is an example of reinforcing members, and the Ta core 31 is an example of reinforcing core materials. The Ta filaments 30 are disposed around the filament assembly 2 entirely or partially to divide the filament assemblies 2 into plural parts. When the filament assemblies 2 are divided, the Ta filaments 30 are disposed such that the respective Sn filaments 23 are not adjacent to each other. By disposing the Ta filaments 30 as the reinforcing members in a mesh shape (honeycomb shape) inside the Cu tube 5, it is possible to provide the strength higher than the case of disposing the Ta filaments 30 only at a center part of the Cu tube 5 and to suppress a compressive strain.

It is preferable that the numbers of the Nb filaments 20 and the Sn filaments 23 composing the filament assembly 2 after being divided are equal to each other, however, the present invention is not limited thereto. The numbers of the Nb filaments 20 and the Sn filaments 23 may be different from each other.

The characteristics required for the Ta filament 30 as the reinforcing filaments are as follows. Since the Ta filament 30 is provided for reinforcing Nb₃Sn, the Ta filament 30 should have the strength higher than that of Nb₃Sn. Since the Ta filament 30 is disposed in the Nb₃Sn filaments, the Ta filament 30 should neither react with Nb₃Sn nor deteriorate the superconducting characteristics.

Therefore, a material of the Ta core 31 of the Ta filament 30 is not limited to Ta and Ta-alloy. For example, the material of the Ta core 31 may comprise at least one metal selected from a group consisting of Ta, Ta-alloy, tungsten (W), W-alloy, niobium (Nb), Nb-alloy, titanium (Ti), Ti-alloy, molybdenum (Mo), Mo-alloy, vanadium (V), V-alloy, zirconium (Zr), Zr-alloy, hafnium (Hf) and Hf-alloy. Among the materials as listed above, Ta or Ta-alloy is preferable, since the drawing process workability of Ta and Ta-alloy (when composite) with Nb, Cu, Sn and the like is excellent.

In the present embodiment, although each of the Nb filament 20, the Sn filament 23 and the Ta filament 30 comprises the same cross-section with the same size, but the Nb filament 20, the Sn filament 23 and the Ta filament 30 may have different sizes, and may have the other cross-section such as polygonal shape e.g., triangular, rectangular or circular shape. However, it is preferable that each of the Nb filament 20, the Sn filament 23 and the Ta filament 30 comprises a hexagonal shape, since a plurality of the Nb filaments 20, the Sn filaments 23 and the Ta filaments 30 can be respectively bundled without gap, and also preferable from the view point of processing. Further, if the Nb filament 20, Sn filament 23 and Ta filament 30 have different sizes, the design of the device will be complicated and more gaps between the filaments may be generated compared with the case of using the filaments having the same size. Therefore, it is preferable that respective filaments have the same size.

(Method for Manufacturing an Nb₃Sn Superconducting Wire)

Next, an example of methods for manufacturing an Nb₃Sn superconducting wire will be explained below.

(1) Manufacturing of a Precursor for an Nb₃Sn Superconductor Wire

At first, the Nb core 21 is inserted into a Cu pipe with a predetermined size to provide a composite material. This composite material is area-reduced (i.e. conducting an area reduction process) by die drawing (wire drawing) in which this composite material is put through a die having an opening having a hexagonal cross-section to provide the Nb filament 20 having a hexagonal cross-section.

Next, the Sn core 24 is inserted into a Cu pipe with a predetermined size to provide a composite material. This composite material is area-reduced by die drawing in which this composite material is put through a die having an opening having a hexagonal cross-section to provide the Sn filament 23 having a hexagonal cross-section.

Next, the Ta core 31 is inserted into a Cu pipe with a predetermined size to provide a composite material. This composite material is area-reduced by die drawing in which this composite material is put through a die having an opening having a hexagonal cross-section to provide the Ta filament 30 having a hexagonal cross-section as the reinforcing member.

Next, the Ta barrier layer 4 is formed by winding a Ta sheet for a predetermined number of layers at an inner surface of a Cu tube 5 with a predetermined size. Inside the Ta barrier layer 4, the filament assemblies 2 each of which comprises a predetermined number of the Nb filaments 20 and a predetermined number of the Sn filaments 23 are divided into a predetermined number of parts by a predetermined number of the Ta filaments 30 such that the Sn filaments 23 are not adjacent to each other, to provide a multicore billet (multicore composite material). The multicore billet is area-reduced by the die drawing in which the multicore billet is put through a die having an opening with a circular cross-section, to provide a precursor 1 for an Nb₃Sn superconductor wire having a circular cross-section.

(2) Heat-Treatment of the Precursor 1 for an Nb₃Sn Superconductor Wire

The precursor 1 for an Nb₃Sn superconductor wire is heat-treated at a temperature ranging from 650 degrees Celsius to 750 degrees Celsius for about 100 hours. Sn of the Sn cores 24 is diffused into the Nb cores 21 by the heat treatment, so that Nb₃Sn is produced. Cu—Sn based alloy is formed from Sn of the Sn cores 24 and Cu of the Cu coating layer 25 of the Sn filament 23, the Cu coating layer 22 of the Nb filament 20 and the Cu coating layer 32 of the Ta filament 30. As a result, the Nb₃Sn superconducting wire is produced.

### Effects of the Embodiment

According to the precursor 1 for the Nb₃Sn superconductor wire in this embodiment, the following effects can be obtained.

(a) Since the Nb filaments 20 constituting the filament assembly 2 can be disposed to be close to each other, the number of the Nb filaments 20 can be increased, so that a total cross-sectional area of the Nb cores 21 with respect to the lateral cross-sectional area of the precursor 1 for the Nb₃Sn superconductor wire can be increased. As a result, a high electric field current density (Jc) of 1800 A/mm² or more can be provided.

(b) The compressive strain can be suppressed more than the case of disposing the reinforcing member only at the center of the Cu tube 5, by arranging the Ta filaments 30 as the reinforcing member in honeycomb shape inside the Cu tube 5. As a result, a degradation rate (Jc₁/Jc₀) of the critical current density when the compression is applied becomes 0.7 or more, wherein Jc₁ is a critical current value when the compression is applied, and Jc₀ is a critical current value when the compression is not applied, so that the degradation in superconducting characteristics can be suppressed.

### EXAMPLES

Next, Examples of the present invention and comparative examples will be explained below.

### Example 1

Firstly, a method for manufacturing the precursor 1 for the Nb₃Sn superconductor wire in Example 1 will be explained below.

At first, Nb-1 wt % Ta alloy rod (Nb core 21) having an outer diameter of 20 mm was inserted into a Cu pipe having an outer diameter of 24 mm and an inner diameter of 20.2 mm to provide a composite material. This composite material was area-reduced by die drawing in which this composite material is put through a die having an opening having a hexagonal cross-section to provide the Nb filament 20 having a hexagonal cross-section in which a distance between opposite sides is 1 mm.

Next, Sn-alloy material containing 2 wt % of Ti (Sn-2 wt % Ti) (Sn core 24) having an outer diameter of 20 mm was inserted into a Cu pipe having an outer diameter of 23 mm and an inner diameter of 20.2 mm to provide a composite material. This composite material was area-reduced by die drawing in which this composite material is put through a die having an opening having a hexagonal cross-section to provide the Sn filament 23 having a hexagonal cross-section in which a distance between opposite sides is 1 mm.

Next, Ta rod (Ta core 31) having an outer diameter of 20 mm was inserted into a Cu pipe having an outer diameter of 23 mm and an inner diameter of 20.2 mm to provide a composite material. This composite material was area-reduced by die drawing in which this composite material is put through a die having an opening having a hexagonal cross-section to provide the Ta filament 30 having a hexagonal cross-section in which a distance between opposite sides is 1 mm as the reinforcing member.

Based on cross-section sizes of the above materials, ratios of cross-sectional areas of the Cu coating layers 22, 25, and 32 with respect to cross-sectional areas of the Nb core 21, Sn core 24, and Ta core 31 of the Nb filament 20, Sn filament 23, and Ta filament 30 (Hereinafter, referred to as “Cu ratio”) are calculated as 0.42, 0.30, and 0.30, respectively.

Next, a diffusion barrier layer (Ta barrier layer 4) was formed by winding a Ta sheet having a thickness of 0.1 mm for 7 layers at an inner surface of a Cu pipe (Cu tube 5) having an outer diameter of 40 mm and an inner diameter of 33 mm. Inside the Ta barrier layer 4, the filament assembly 2 comprising 456 pieces of Nb filaments 20 and 229 pieces of the Sn filaments 23 was divided into seven parts by 84 pieces of the Ta filaments 30 such that the Sn filaments 23 are not adjacent to each other, to provide a multicore billet (multicore composite material). The multicore billet was area-reduced by the die drawing in which the multicore billet is put through a die having an opening with a circular cross-section, to provide a precursor 1 for an Nb₃Sn superconductor wire having a wire diameter of 1 mm.

Referring to FIG. 1, when focusing on the continuity of the Ta filaments 30, the arrangement of the Ta filaments 30 is six-fold symmetry. The arrangement of the Ta filaments 30 naturally satisfies the condition of two-fold symmetry and three-fold symmetry. In other words, the number of the divided parts of the filament assembly 2 (i.e. the number of the filament assemblies 2) divided by the Ta filaments 30 as the reinforcing filaments is 6n+1 (n is an integer).

The configuration shown in FIG. 1 has an advantage in that this configuration is structurally stable. Further, when the Nb₃Sn superconductor wire is manufactured by heat treatment, the respective superconducting filaments may be closer to each other than expected due to bias of Sn movement, as a result the respective superconducting filaments may be substantially coupled to each other as a superconductor. However, by providing the reinforcing filaments having the size substantially same as the other filaments, it is possible to surely provide the spacing between the Sn filaments 23, thereby reducing the risk of the increase in AC loss.

### Examples 2 and 3

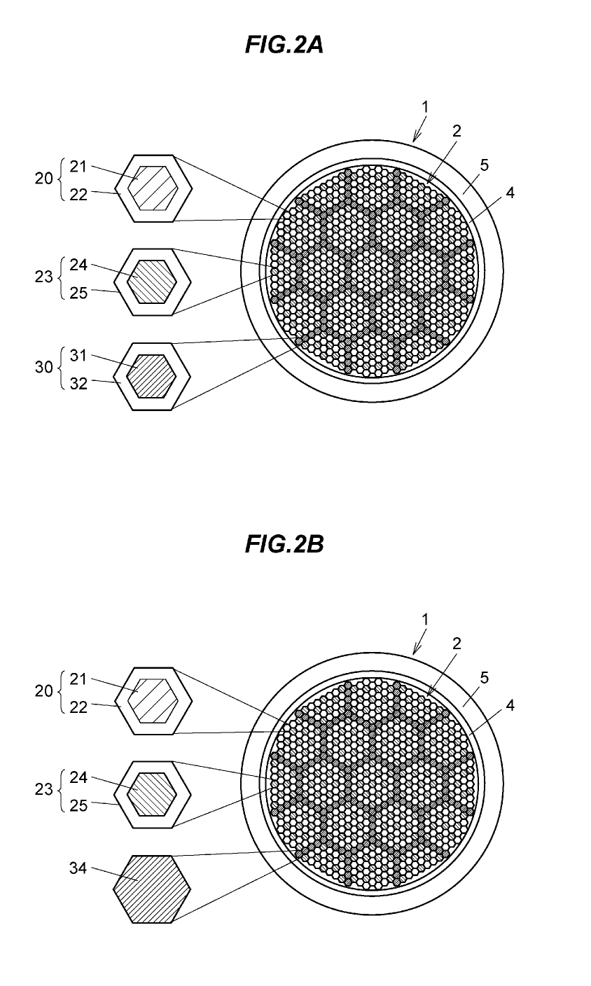

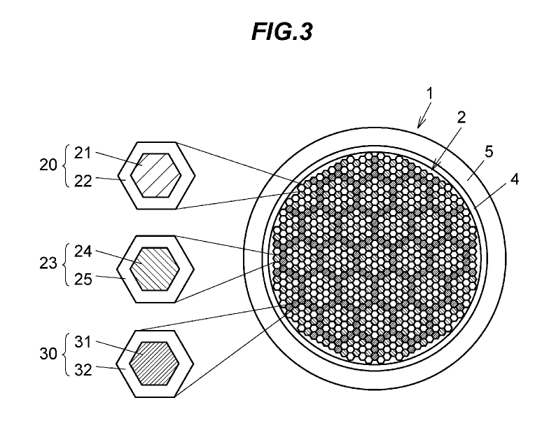

FIG. 2A is a lateral cross-sectional view showing a cross-sectional structure of a precursor for an Nb₃Sn superconductor wire in each of Examples 2, 4 and 5. FIG. 3 is a lateral cross-sectional view showing a cross-sectional structure of a precursor for an Nb₃Sn superconductor wire in Example 3.

The precursor 1 for the Nb₃Sn superconductor wire in each of Examples 2 and 3 was manufactured by the method similar to that in Example 1, except the number of divided parts of the filament assembly 2 with the Ta filaments 30 was varied.

In Example 2, as shown in FIG. 2A, the filament assembly 2 comprising 396 pieces of Nb filaments 20 and 211 pieces of the Sn filaments 23 was divided into nineteen (19) parts by 162 pieces of the Ta filaments 30 such that the Sn filaments 23 are not adjacent to each other, to provide a multicore billet. The multicore billet was area-reduced, to provide a precursor 1 for an Nb₃Sn superconductor wire having a wire diameter of 1 mm.

In Example 3, as shown in FIG. 3, the filament assembly 2 comprising 348 pieces of Nb filaments 20 and 199 pieces of the Sn filaments 23 was divided into thirty seven (37) parts by 222 pieces of the Ta filaments 30 such that the Sn filaments 23 are not adjacent to each other, to provide a multicore billet. The multicore billet was area-reduced, to provide a precursor 1 for an Nb₃Sn superconductor wire having a wire diameter of 1 mm.

Referring to FIG. 2A, the arrangements of the Ta filaments 30 in Examples 2 and 3 are six-fold symmetry, similarly to Example 1. When the sizes of the Nb filament 20 and the Sn filament 23 to be used in the filament assembly 2 are large and the number of the filaments to be used is small, the number of the divided filament assemblies 2 should be reduced as shown in FIG. 1. On the other hand, when the sizes of the Nb filament 20 and the Sn filament 23 to be used in the filament assembly 2 are small and the number of the filaments to be used is large, the number of the divided filament assemblies 2 should be increased as shown in FIG. 2A. However, it should be noted that substantial superconducting characteristics to the total volume of the wire would be relatively reduced when an occupation ratio of Ta is high, since Ta per se does not constitute the superconductor wire.

### Examples 4, 5, and 6

The precursor 1 for the Nb₃Sn superconductor wire in each of Examples 4 and 5 was manufactured by the method similar to that in Example 2, except a cross-sectional area ratio of the Cu coating layer 32 of the Ta filament 30 as the reinforcing member was varied.

In Example 4, as shown in FIG. 2A, Ta rod (Ta core 31) having an outer diameter of 20 mm was inserted into a Cu pipe having an outer diameter of 28 mm and an inner diameter of 20.2 mm to provide a composite material (Cu ratio is 0.67). This composite material was area-reduced to provide the Ta filament 30 having a hexagonal cross-section in which a distance between opposite sides is 1 mm as the reinforcing member. Herein, the Cu ratio is a ratio of a lateral cross-sectional area of the Cu part wherein a total lateral cross-sectional area of all filaments is 1.

In Example 5, as shown in FIG. 2A, a Cu pipe having an outer diameter of 22 mm and an inner diameter of 20.2 mm was prepared. Ta rod (Ta core 31) having an outer diameter of 20 mm was inserted into the aforementioned Cu pipe to provide a composite material (Cu ratio is 0.19). This composite material was area-reduced to provide the Ta filament 30 having a hexagonal cross-section in which a distance between opposite sides is 1 mm as the reinforcing member.

The precursor 1 for the Nb₃Sn superconductor wire in Example 6 was manufactured by the method similar to that in Example 2, except Ta rod having no Cu coating layer 32 (Cu ratio is 0) was processed to provide a Ta filament 34 having a hexagonal cross-section in which a distance between opposite sides is 1 mm as the reinforcing member, as shown in FIG. 2B.

In all of Examples 4, 5, and 6, the filament assembly 2 comprising 396 pieces of Nb filaments 20 and 211 pieces of the Sn filaments 23 was divided into nineteen (19) parts by 162 pieces of the Ta filaments 30 (or 34) such that the Sn filaments 23 are not adjacent to each other, to provide a multicore billet. The multicore billet was area-reduced to provide a precursor 1 for an Nb₃Sn superconductor wire having a wire diameter of 1 mm.

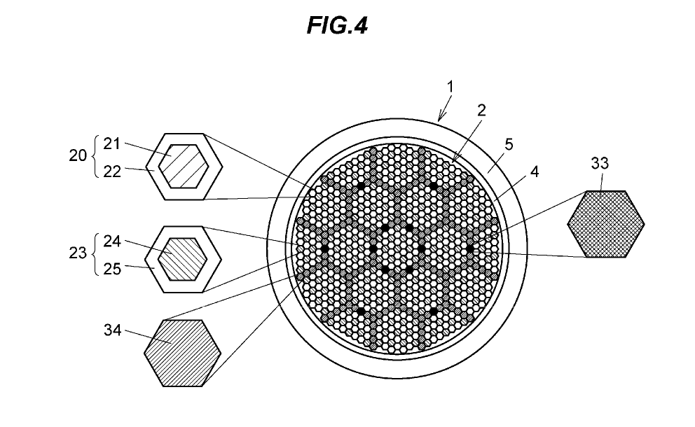

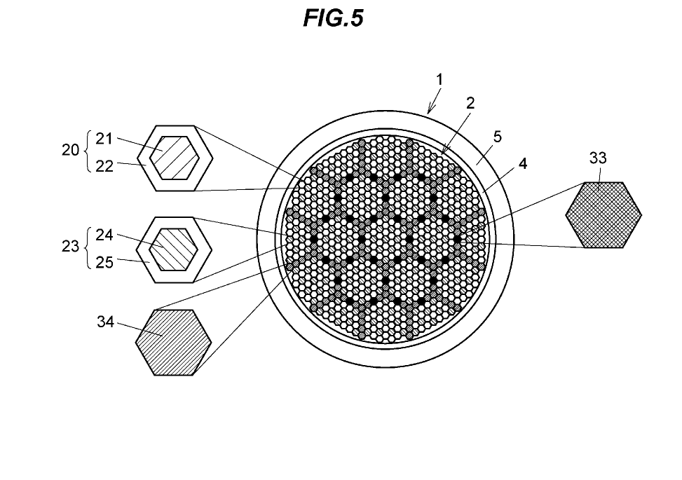

FIG. 4 is a lateral cross-sectional view showing a cross-sectional structure of a precursor for an Nb₃Sn superconductor wire in Example 7. FIG. 5 is a lateral cross-sectional view showing a cross-sectional structure of a precursor for an Nb₃Sn superconductor wire in Example 8.

The precursor 1 for the Nb₃Sn superconductor wire in each of Examples 7 and 8 was manufactured by the method similar to that in Example 6, except a part of the Ta filaments 30 for dividing the filament assembly 2 in the multicore billet is replaced with Cu filaments 33, each of which has the same size as that of the Ta filament 30.

In Example 7, as shown in FIG. 4, the filament assembly 2 comprising 396 pieces of Nb filaments 20 and 211 pieces of the Sn filaments 23 was divided into nineteen (19) parts by 162 pieces of the Ta filaments 34 such that the Sn filaments 23 are not adjacent to each other, and 12 pieces of the Ta filaments 34 disposed in a hexagonal shape were replaced with 12 pieces of the Cu filaments 33 to provide a multicore billet. Therefore, the multicore billet comprises 150 pieces of the Ta filaments 34. The multicore billet was area-reduced to provide a precursor 1 for an Nb₃Sn superconductor wire having a wire diameter of 1 mm.

In Example 8, as shown in FIG. 5, the filament assembly 2 comprising 396 pieces of Nb filaments 20 and 211 pieces of the Sn filaments 23 was divided into nineteen (19) parts by 162 pieces of the Ta filaments 34 such that the Sn filaments 23 are not adjacent to each other, and 30 pieces of the Ta filaments 34 disposed in a hexagonal shape were replaced with 30 pieces of the Cu filaments 33 to provide a multicore billet. Therefore, the multicore billet comprises 132 pieces of the Ta filaments 34. The multicore billet was area-reduced to provide a precursor 1 for an Nb₃Sn superconductor wire having a wire diameter of 1 mm.

In both of Examples 7 and 8, the material replacing a part of Ta filaments 34 is not limited to the Cu filament 33, and the Nb filament 20 or the Sn filament 23 may be used as the replacing material.

### Comparative Example 1

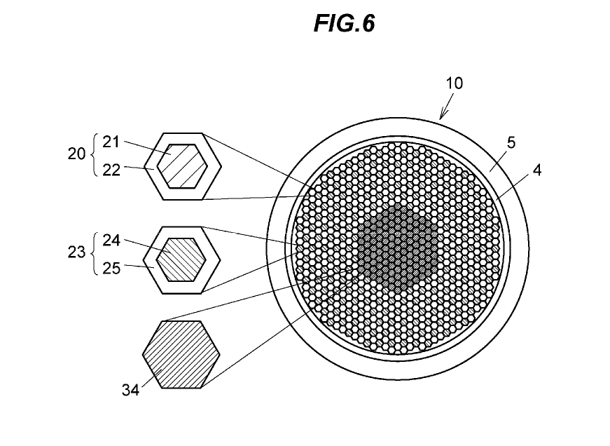

FIG. 6 is a lateral cross-sectional view showing a cross-sectional structure of a precursor for an Nb₃Sn superconductor wire manufactured by the conventional internal Sn diffusion method in comparative examples 1 and 2.

In comparative example 1, Nb filaments 20 and Sn filaments 23 that are same as those in Example 1 were produced similarly to Example 1.

Next, Ta rod (Cu ratio is 0) was area-reduced to provide a Ta filament 34 with no Cu coating layer 32, which has a hexagonal cross-section in which a distance between opposite sides is 1 mm as the reinforcing member. The Cu ratios of the Nb filament 20, Sn filament 23, and Ta filament 34 are calculated as 0.42, 0.30, and 0, respectively.

Next, a diffusion barrier layer (Ta barrier layer 4) was formed by winding a Ta sheet having a thickness of 0.1 mm for seven layers at an inner surface of a Cu pipe (Cu tube 5) having an outer diameter of 40 mm and an inner diameter of 33 mm. Inside the Ta barrier layer 4, 127 pieces of the Ta filaments 34 are disposed at a center of an inside portion of the Ta barrier layer 4, and 432 pieces of Nb filaments 20 and 210 pieces of the Sn filaments 23 were disposed at an outer periphery of the Ta filaments 34 such that the Sn filaments 23 are not adjacent to each other, to provide a multicore billet. The multicore billet was area-reduced, to provide a precursor 10 for an Nb₃Sn superconductor wire having a wire diameter of 1 mm.

### Comparative Example 2

A precursor 10 for an Nb₃Sn superconductor wire in comparative example 2 was manufactured similarly to the comparative example 1, except the Cu ratios of the Cu coating layer 22 of the Nb filament 20 and the Cu coating layer 25 of the Sn filament 23 were increased compared with the comparative example 1.

At first, Nb-1 wt % Ta alloy rod (Nb core 21) having an outer diameter of 20 mm was inserted into a Cu pipe having an outer diameter of 26 mm and an inner diameter of 20.2 mm to provide a composite material. This composite material was area-reduced to provide the Nb filament 20 having a hexagonal cross-section in which a distance between opposite sides is 1 mm.

Next, Sn-alloy material containing 2 wt % of Ti (Sn-2 wt % Ti) (Sn core 24) having an outer diameter of 20 mm was inserted into a Cu pipe having an outer diameter of 24 mm and an inner diameter of 20.2 mm to provide a composite material. This composite material was area-reduced to provide the Sn filament 23 having a hexagonal cross-section in which a distance between opposite sides is 1 mm.

The Cu ratios of the Nb filament 20 and the Sn filament 23 are 0.67 and 0.42, respectively.

The Ta filament 34 was produced similarly to the comparative example 1.

Next, a diffusion barrier layer (Ta barrier layer 4) was formed by winding a Ta sheet having a thickness of 0.1 mm for seven layers at an inner surface of a Cu pipe (Cu tube 5) having an outer diameter of 40 mm and an inner diameter of 33 mm. Inside the Ta barrier layer 4, 127 pieces of the Ta filaments 34 are disposed at a center of an inside portion of the Ta barrier layer 4, and 432 pieces of Nb filaments 20 and 210 pieces of the Sn filaments 23 were disposed at an outer periphery of the Ta filaments 34 such that the Sn filaments 23 are not adjacent to each other, to provide a multicore billet. The multicore billet was area-reduced, to provide a precursor 10 for an Nb₃Sn superconductor wire having a wire diameter of 1 mm. The precursor 10 for an Nb₃Sn superconductor wire in comparative example 2 was manufactured similarly to the comparative example 1, except the aforementioned process.

### Comparative Example 3

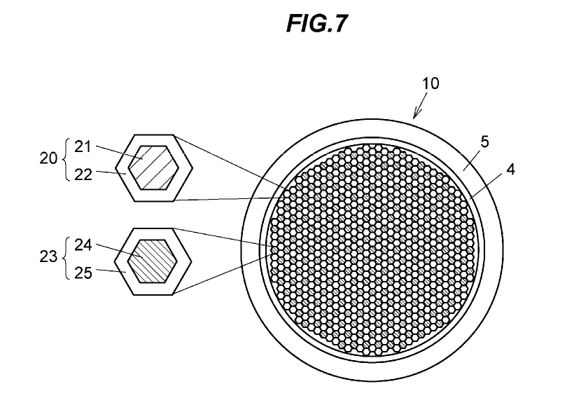

FIG. 7 is a lateral cross-sectional view showing a cross-sectional structure of a precursor for an Nb₃Sn superconductor wire manufactured by the conventional internal Sn diffusion method in comparative example 3.

A precursor 10 for an Nb₃Sn superconductor wire in comparative example 3 was manufactured as a wire including no reinforcing member.

At first, Nb-1 wt % Ta alloy rod (Nb core 21) having an outer diameter of 20 mm was inserted into a Cu pipe having an outer diameter of 26 mm and an inner diameter of 20.2 mm to provide a composite material. This composite material was area-reduced to provide the Nb filament 20 having a hexagonal cross-section in which a distance between opposite sides is 1 mm.

Next, Sn-alloy material containing 2 wt % of Ti (Sn-2 wt % Ti) (Sn core 24) having an outer diameter of 20 mm was inserted into a Cu pipe having an outer diameter of 24 mm and an inner diameter of 20.2 mm to provide a composite material. This composite material was area-reduced to provide the Sn filament 23 having a hexagonal cross-section in which a distance between opposite sides is 1 mm.

Next, a diffusion barrier layer (Ta barrier layer 4) was formed by winding a Ta sheet having a thickness of 0.1 mm for seven layers at an inner surface of a Cu pipe (Cu tube 5) having an outer diameter of 40 mm and an inner diameter of 33 mm. Inside the Ta barrier layer 4, 516 pieces of Nb filaments 20 and 253 pieces of the Sn filaments 23 were disposed such that the Sn filaments 23 are not adjacent to each other, to provide a multicore billet. The multicore billet was area-reduced to provide a precursor 10 for an Nb₃Sn superconductor wire having a wire diameter of 1 mm.

(Evaluation of Superconducting Characteristics)

Table 1 shows respective structures of Examples 1 to 8 and comparative examples 1 to 3 and evaluation result of superconducting characteristics.

TABLE 1

| | | | | | | | | | | Comparative | | |
|---|---|---|---|---|---|---|---|---|---|---|---|---|
| | | Examples | | | | | | | | Examples | | |
| Items | | 1 | 2 | 3 | 4 | 5 | 6 | 7 | 8 | 1 | 2 | 3 |
| Filament Cu | Nb | 0.42 | 0.42 | 0.42 | 0.42 | 0.42 | 0.42 | 0.42 | 0.42 | 0.42 | 0.67 | 0.67 |
| ratio | Sn | 0.30 | 0.30 | 0.30 | 0.30 | 0.30 | 0.30 | 0.30 | 0.30 | 0.30 | 0.42 | 0.42 |
| | Ta | 0.30 | 0.30 | 0.30 | 0.67 | 0.19 | 0 | 0 | 0 | 0 | 0 | 0 |
| The number | Nb | 456 | 396 | 348 | 396 | 396 | 396 | 396 | 396 | 432 | 432 | 516 |
| of filaments | Sn | 229 | 211 | 199 | 211 | 211 | 211 | 211 | 211 | 210 | 210 | 253 |
| (Filament | Ta | 84 | 162 | 222 | 162 | 162 | 162 | 150 | 132 | 127 | 127 | 0 |
| Number) | Cu | — | — | — | — | — | — | 12 | 30 | — | — | — |
| Filament | Nb | 22.1 | 22.1 | 22.1 | 22.1 | 22.1 | 22.1 | 22.1 | 22.1 | 22.1 | 20.4 | 20.4 |
| Diameter | | | | | | | | | | | | |
| [μm] | | | | | | | | | | | | |
| Reinforcing | Ratio | 0.05 | 0.10 | 0.13 | 0.07 | 0.10 | 0.12 | 0.12 | 0.10 | 0.10 | 0.10 | 0 |
| member | Division | 7 | 19 | 37 | 19 | 19 | 19 | 19 | 19 | — | — | — |
| | number | | | | | | | | | | | |
| | Division | 285 | 163 | 111 | 163 | 163 | 163 | 163 | 163 | 800 | 800 | 800 |
| | dimension | | | | | | | | | | | |
| | [μm] | | | | | | | | | | | |

| | | | | | | | | | | | |
|---|---|---|---|---|---|---|---|---|---|---|---|
| Jc₀ (No-strain) | 2450 | 2130 | 1870 | 2110 | 2150 | 2100 | 2120 | 2140 | 2320 | 1980 | 2350 |
| [A/mm²] | | | | | | | | | | | |
| Jc₁ | 1750 | 1710 | 1670 | 1660 | 1720 | 1650 | 1700 | 1740 | 1410 | 1220 | 1170 |
| (Lateral compression | | | | | | | | | | | |
| of 75 kgf) | | | | | | | | | | | |
| [A/mm²] | | | | | | | | | | | |
| Degradation rate | 0.71 | 0.80 | 0.89 | 0.79 | 0.80 | 0.79 | 0.80 | 0.81 | 0.61 | 0.62 | 0.50 |
| (Jc₁/Jc₀) | | | | | | | | | | | |
| Effective filament | 295 | 165 | 115 | 195 | 165 | 160 | 195 | 200 | Non- | 160 | 180 |
| diameter D_{eff} | | | | | | | | | detectable | | |
| [μm] | | | | | | | | | | | |
| 0.2% proof stress | 150 | 210 | 250 | 180 | 210 | 240 | 220 | 200 | 210 | 200 | 110 |
| [MPa] | | | | | | | | | | | |

Firstly, the “filament Cu ratio” is a ratio of a lateral cross-sectional area of a Cu part of each filament wherein a total lateral cross-sectional area of all filaments is 1.

The number of filaments (the “filament number”) is the number of filaments shown in each item (for this case, the filament number is the same number as the number of filaments).

The “filament diameter (Nb)” is a diameter of the Nb core 21 before Nb₃Sn is produced. The “filament diameter (Nb)” is shown as a reference value, since the diffusion of Sn by the heat treatment during the production of Nb₃Sn superconductor, and Nb₃Sn is produced at apparent locations of the Nb cores (however, since the volume is increased, the boundary in a precise sense is magnified outwardly).

The “Ratio” of the “Reinforcing member” is a ratio of total volume of the Ta reinforcing members (excluding the Cu filament) to a total volume of the precursor 1 for the Nb₃Sn superconductor wire including the Cu tube 5 comprising of Cu or Cu-alloy.

Particularly in Examples 7 and 8 to be described later, the volume of the Cu filaments 33 that replace a part (several pieces) of the part of Ta filaments 30 as the reinforcement filaments is counted in a numerator.

For each of Examples and comparative examples manufactured as described above, a part of the wire having the wire diameter of 1 mm was heat-treated at a temperature of 500 degrees Celsius for 100 hours and at a temperature 700 degrees Celsius for 100 hours (i.e. 500° C.×100 hours+700° C.×100 hours) to prepare a sample 100 for evaluating the superconducting characteristics.

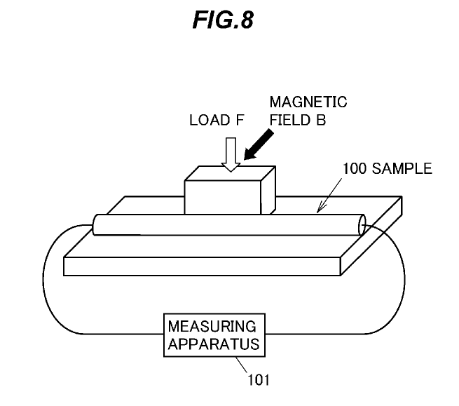

FIG. 8 is an explanatory diagram for showing the measurement process of the critical current. Electric current was applied to the sample 100 which has been prepared as described above in liquid helium (at a temperature of 4.2K) while applying magnetic field of 12 T (tesla) to the sample 100, and the critical current value was measured with the use of a measuring apparatus 101. A critical current value Ic is defined by a voltage generation of 0.1 μV per 1 cm of wire length (1 μV/cm). Non-Cu Jc (non-copper part critical current density) was calculated by dividing the measured critical current value Ic by a cross-sectional area of the multicore wire except a stabilized copper part. Two samples were prepared for each of Examples and comparative examples. The non-Cu Jc (critical current density) of the sample measured without applying a compression (distortion) is Jc₀. Similarly, the non-Cu Jc (critical current density) was measured in the state of applying a load (lateral compressive load) F of 75 kg (735N) to the sample wire from a direction perpendicular to a longitudinal direction of the sample wire via a compression jig installed at a side face of the sample in the magnetic field B of 12 T in the liquid helium, to calculate the critical current density Jc₁.

(Degradation Rate)

The degradation rate of the critical current density Jc by the compressive load was derived by calculating a ratio of Jc₁ to Jc₀ (Jc₁/Jc₀, degradation rate).

In the superconductor wire in the comparative example 3 including no reinforcing member, the degradation rate due to the lateral compression was 0.5. Similarly, in the super conductor wires in the comparative examples 1 and 2 including the reinforcing members at the center part of the multicore wire, the degradation rate due to the lateral compression was about 0.6.

On the other hand, as to Examples 1 to 8 of the present invention, the degradation rate of Example 1 in which the division number (the number of divided parts) is 7 (the smallest number) was about 0.7 and the degradation rate of Example 3 in which the division number is 37 (the largest number) was about 0.9. Therefore, it is confirmed that the effect of suppressing the degradation in superconducting characteristics due to the lateral compression can be obtained by disposing the reinforcing members in honeycomb shape in the cross-section of the multicore wire.

(Proof Stress)

Tensile stress test was carried out at a room temperature on the sample in each of Examples and comparative examples after the heat treatment, in order to measure 0.2% proof stress. Comparing a ratio of the composite reinforcing members with the 0.2% proof stress of each sample, it is confirmed that the 0.2% proof stress increases in accordance with the increase in the ratio of the reinforcing members.

As shown in Table 1, it is preferable that the ratio of the reinforcing member is 10% or more of a total lateral cross-sectional area of the filaments, in order to provide 200 MPa or more of the 0.2% proof stress as in Examples 2, 3, and 5 to 8.

(Magnetic Susceptibility)

Magnetic susceptibility measurement was carried out on the sample 100 in each of Examples and comparative examples after the heat treatment. The measurement was carried out under the measurement condition of a measuring temperature of 4.5K in a magnetic field varying from 5.5 to −5.5 T (i.e. 0 T→5.5 T→0 T→5.5 T→0 T).

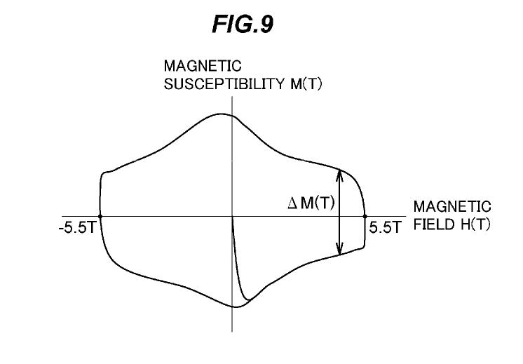

FIG. 9 is a graph showing the magnetic susceptibility of the sample 100 for the magnetic field applied to the sample 100.

An effective filament diameter d_{eff} of Nb₃Sn was calculated from the measured magnetic susceptibility ΔM by using a following equation,

d_{eff}[μm]=3π/4μ₀·ΔM [T]/Jc [A/mm²],

(3π/4μ₀·ΔM [T]/Jcₛᵢ [A/m²]×10⁶)

wherein μ₀ is a magnetic permeability in vacuum (1×10⁻⁷), and π is a circular constant.

As shown in Table 1, the effective filament diameter d_{eff} in each of Examples 1 to 8 was substantially equivalent to a dimension of the part divided by the reinforcing member (“division dimension” [μm] in column of “reinforcing member”). In other words, respective Nb₃Sn filaments are electromagnetically coupled to each other inside the part divided by the reinforcing members, while the Nb₃Sn filaments are electromagnetically isolated (separated) from each other between the regions divided by the reinforcing members. Therefore, it is confirmed that the arrangements of the reinforcing members in Examples 1 to 8 are effective for the electromagnetic isolation (separation) of the Nb₃Sn filaments.

As for the comparative examples 1 to 3, the magnetic susceptibility in the comparative example 1 was too high to be measured.

In the comparative example 1, although the Nb filaments 20, Sn filaments 23, and Ta filaments 34 having the same Cu ratios as those in the Examples 6 to 8 are used, it is assumed that the Nb₃Sn filaments were disposed too closely so that the Nb₃Sn filaments are coupled to each other all over the superconductor wire.

In the comparative examples 2 and 3, although the spacing between the Nb₃Sn filaments was increased by increasing the Cu ratios of the Nb filament 20 and Sn filament 23, the effective filament diameter d_{eff} was reduced to about 160 μm or 180 μm.

Therefore, as to Examples of the present invention, it is understood that the Nb₃Sn filaments can be surely isolated (separated) from each other by the reinforcing members even though the Cu ratio is small and the Nb₃Sn filaments are disposed closely.

In Examples 4, 5 and 6, the Cu ratio of the reinforcing member is different from that in Examples 1 to 3.

In Example 6 which uses the reinforcing member having no Cu coating, namely, the Cu ratio of the Ta filament is 0, as shown in Table 1, the cross-sectional area ratio of the reinforcing members is 12% which is the largest value among Examples 4, 5 and 6, so that the 0.2% proof stress is 240 MPa which is also the largest value among Examples 4, 5, and 6.

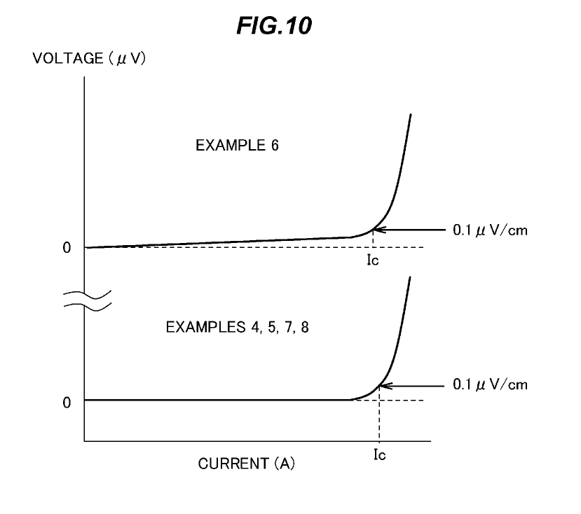

As to the current-voltage curve in the Jc measurement, the voltage is not generated when the current value is equal to or less than the critical current value Ic in a normal case. However, as shown in FIG. 10, the current-voltage curve of Example 6 inclines (slants) when the current value is equal to or less than critical current value Ic, so that it is confirmed that the voltage is generated in proportional to the electric current.

In the cross-sectional structure of Example 6, since the reinforcing member has no Cu coating, the filaments are completely separated from each other by the reinforcing members. Therefore, it is assumed that the supercurrent must flow through the reinforcing member having a high electric resistance in order to flow into an inner part of the wire separated by the current reinforcing members from an electric current terminal installed at an outer part of the wire, so that the voltage is generated at this time.

On the other hand, in Examples 4 and 5, as shown in the current-voltage curve in FIG. 10, the voltage is not generated when the current value is equal to or less than the critical current value Ic. Therefore, it is assumed that the supercurrent can flow through Cu having a low electric resistance into an inner part surrounded by the reinforcing members, since the reinforcing member has the Cu coating in Examples 4 and 5. Therefore, it is not appropriate to completely surround the filament assembly 2 with the reinforcing members. In Example 5, since the thickness of each of the Cu coating layers 22, 25, and 32 is 3 μm while the thickness of the outer diameter of each of the filaments 20, 23 and 30 is 20 μm, it is concluded that a covering ratio is preferably 90% or less of a peripheral length.

In Example 5, the Ta reinforcing members were disposed to surround the assemblies of the Nb filaments and Sn filaments. In the Ta reinforcing member used for Example 5, an outer diameter of the Ta reinforcing member was 26.3 μm, a thickness of the Cu coating was 1.1 μm, and a diameter of the Ta filament was 24.2 μm. A length ratio of Ta to a peripheral length for surrounding the assembly is equivalent to a ratio of the diameter of Ta filament (except the Cu coating) to the diameter of the Ta reinforcing member. A length ratio of Cu to the peripheral length for surrounding the assembly is equivalent to a ratio of the (twice) thickness of the Cu coating to the diameter of the Ta reinforcing member.

In Example 5, the ratio of Ta was about 91% since the diameter of the Ta filament was 24.2 μm while the diameter of the Ta reinforcing member was 26.3 μm, and the ratio of Cu coating was about 9% as a remaining part. Since the unnecessary voltage generation was suppressed by coating the Ta filament by Cu with the above covering ratio in Example 5, it is preferable that a ratio of the component of the reinforcing material (i.e. the Ta part excluding the Cu part) to the reinforcement member for surrounding the assembly is 90% or less.

In the case of dividing the assemblies of filaments by the Ta reinforcing members, it is possible to reduce the ratio of the Ta reinforcing members for surrounding the filaments (the Nb filaments 20 and Sn filaments 23) by replacing a part of the reinforcing members with other members such as Nb, Sn, or Cu.

In Examples 7 and 8, the Ta filaments having no Cu coating were used as the reinforcing member, and a part of the Ta reinforcing members was replaced by the Cu filaments. In Example 7, two (11%) of eighteen Ta filaments disposed in the hexagonal shape were replaced with two Cu filaments 33. In Example 8, six (33%) of eighteen Ta filaments were replaced with six Cu filaments 33.

For these cases, the Cu filament 33 becomes a part of the Cu matrix similarly to the Cu coating layers 22, 25, and 32 by the heat treatment conducted in the superconductor producing process.

As described above, when using the Ta filament having no Cu coating, the Cu matrix part should be formed at a part of the boundary of the filament assembly 2, rather than surrounding the filament assembly 2 completely by Ta. According to this structure, the electrical current is flown more easily through the assembly disposed inside the filament assembly 2 which is adjacent to the Cu tube 5, so that the superconducting characteristics of the entire part of the Nb₃Sn superconductor wire would be improved compared with Example 6.

As described above, in Examples 7 and 8, the superconducting characteristics of the whole Nb₃Sn superconductor wire are improved while the mechanical strength is raised. In addition, since the outermost filament assembly 2 adjacent to the Cu tube 5 contacts with the Cu tube 5 (via the Ta barrier layer 4), the electric current is flown therethrough relatively easily. Accordingly, in Examples 7 and 8, the Ta filaments 30, 34 for separating the outermost filament assemblies 2 from each other are not replaced with the Cu filaments 33. It should be noted however that this configuration does not refrain from replacing a part of the Ta filaments 30, 34 for separating the outermost filament assemblies 2, 2 with the Cu filaments 33.

As to the current-voltage characteristic in Examples 7 and 8, the voltage was not generated when the electric current was equal to or less than the critical current density value Ic. The effective filament diameter d_{eff} of Example 8 was 500 μm which is greater than that in Example 7. It is assumed that the electromagnetic coupling was increased in accordance with the decrease in isolation of the filaments (the Nb filaments 20 and Sn filaments 23) by the reinforcing members. Therefore, the covering ratio for surrounding the filament assembly 2 is preferably 70% or more and 90% or less of the peripheral length of the filament assembly 2.

Although the invention has been described, the invention according to claims is not to be limited by the above-mentioned embodiments and examples. Further, please note that not all combinations of the features described in the embodiments and the examples are not necessary to solve the problem of the invention.

What is claimed is:

1. An Nb₃Sn superconductor wire manufactured by heating a precursor for an Nb₃Sn superconductor wire, the precursor comprising:
a Cu tube comprising Cu or Cu-alloy;
assemblies, each of which comprises Nb filaments disposed in the Cu tube, each of the Nb filaments comprising an Nb core comprising Nb or Nb-alloy, and Sn filaments disposed in the Cu tube, each of the Sn filaments comprising a Sn core comprising Sn or Sn-alloy; and
reinforcing filaments disposed in the Cu tube for dividing the assemblies such that the assemblies are not adjacent to each other,
wherein Sn in the Sn core is diffused into the Nb core by the heating to produce Nb₃Sn.

2. The Nb₃Sn superconductor wire according to claim 1, wherein a number of the assemblies divided by the reinforcing filaments is 6n+1 (n is an integer).

3. The Nb₃Sn superconductor wire according to claim 1, wherein a part of the reinforcing filaments comprises a core and a coating layer for coating the core, and the core comprises at least one metal selected from a group consisting of Ta, Ta-alloy, W, W-alloy, Nb, Nb-alloy, Ti, Ti-alloy, Mo, Mo-alloy, V, V-alloy, Zr, Zr-alloy, Hf and Hf-alloy.

4. The Nb₃Sn superconductor wire according to claim 1, wherein a part of the reinforcing filaments is replaced with Cu filaments comprising Cu or Cu-alloy.

5. The Nb₃Sn superconductor wire according to claim 1, wherein the reinforcing filaments are disposed to surround 70% or more and 90% or less of a periphery of the assemblies after being divided.

6. A method for manufacturing an Nb₃Sn superconductor wire, comprising:
conducting area reduction on a Cu pipe to which an Nb core comprising Nb or Nb-alloy is inserted, thereby providing Nb filaments;
conducting area reduction on a Sn core comprising Sn or Sn-alloy, or on a Cu pipe to which the Sn core is inserted, thereby providing Sn filaments;
conducting area reduction on a reinforcing core, or on a Cu pipe to which the reinforcing core is inserted, thereby providing reinforcing filaments;
forming a barrier layer comprising a metal selected from the group consisting of Ta, Ta-alloy, Nb and Nb-alloy at an inner surface of a Cu tube;
disposing assemblies comprising the Nb filaments and the Sn filaments inside the barrier layer with dividing the assemblies by the reinforcing filaments, such that the assemblies are not adjacent to each other;
conducting area reduction on the Cu tube, thereby providing a precursor for the Nb₃Sn superconductor wire;
heating the precursor for the Nb₃Sn superconductor wire to diffuse Sn in the Sn core into the Nb core, thereby producing Nb₃Sn.
